(19) United States
(12) Patent Application Publication
(10) Pub. No.: US 2009/0273839 A1
(43) Pub. Date: Nov. 5, 2009

(54) Method for constructing a phase conjugate mirror

(76) Inventor: Joseph Reid Henrichs, Lees Summit, MO (US)

Correspondence Address: Joseph Reid Henrichs, 641 Northeast Swann Circle, Lees Summit, MO, 64086, US

(21) Appl. No.: 12/150,613

(22) Filed: Apr. 30, 2008

(51) Int. Cl. G02B 5/124; C30B 23/04; C25D 7/08; B32B 7/00

(52) U.S. Cl. 359/530; 428/119; 117/106; 117/200; 205/116; 359/529

(57) ABSTRACT

A method that provides for a phase conjugate mirror 10 having a gallium-arsenide substrate 11 with a generally cubic crystalline lattice and a number of gallium-arsenide crystal projections 14 extending from said substrate 11, the projections each having three generally planar surfaces 15, 16, 17, where the surfaces each being generally obliquely oriented with respect to a plane of said substrate 11, the plane substantially corresponding to a (111) crystal face, the projections 14 being oriented along the plane 13 to provide a predetermined corner-cube array pattern 10, the device including a number of implant sites 25 spaced apart from one another along the substrate 11 to define a pattern 40, and forming a number of corner-cubes articles having a shape substantially corresponding to the corner-cube array 10 pattern 40, wherein the articles each have a number of cube-corner projections 14 spaced apart from each other by a minimum distance of 1 micron. Further, providing for a method of slowing annealing that re-crystallizes the implant sites 25, which located between and slightly underneath the corner-cube projections, where the implant sites 25 are embedded within the substrate material.

### BACKGROUND OF THE INVENTION

1. Field of the Invention

“Optical Phase Conjugation” (OPC) is described by optical and laser physicists as being a nonlinear optical effect that can be used to precisely reverse both the direction of propagation and the overall phase for each plane-wave in an arbitrary beam of light.

2. Background of the Invention

A beam of light, being retro-reflected by a “Phase Conjugation Mirror” (PCM), retraces its path of propagation backwards to its point of origin. OPC is an optical process that is expressed by the equation

kᵢₙ=kₒᵤₜ.

When used to provide retro-reflection in an optical feedback system, such as the system used in lasers, a PCM provides for some highly desirable effects; e.g., suppression of “Amplified Spontaneous Emission” (ASE), the neutralization of filamentation (i.e., so called self-focusing effect problem by those well versed in the art) that occurs in broad-area high-powered laser-diodes (e.g., Broad-Area configured Vertical Cavity Surface Emitting Laser diodes), mode-locking in laser-diode arrays, and a loosening of the narrow laser-cavity design criteria that restricts current VCSEL designs to multimode laser-emission output and low-power application.

Regrettably, most current forms of OPC are active and require multiple lasers, multiple laser beams, elaborate pumping schemes, and exotic crystalline non-linear materials which are lattice mismatched to semiconductor materials. This makes the use of active OPC in laser systems problematic and costly, with monolithic integration being nearly impossible in semiconductor laser diodes.

Additionally, current forms of active OPC (e.g., Four-Wave Mixing, Three-Wave Mixing, Raman Scattering, and Stimulated Brillouin Scattering) suffer from what is sometimes called the frequency-scanning problem, which is typically solved using complex and costly laser-cavity configurations and complex design schemes. For examples of active OPC please see ‘Phase Conjugate Laser Optics’, pages 301 through 329, edited by Arnard Brignon and Jean-Pierre Huignard, publish 2004, by John Wiley and Sons, Inc. incorporated herein for reference purposes only.

The alternative to active OPC is to use a passive corner-cube array in place of an active PCM to provide OPC. Corner-cube arrays are sometimes called pseudo phase-conjugation mirrors and also provide kᵢₙ=kₒᵤₜ, but they do it without the use of the exotic mixing, refractive materials, and/or photon scattering schemes typical for active OPC, ergo the term passive PCM. Pseudo phase-conjugating mirrors have the advantage of being passive, broadband; not requiring the use of multiple lasers, elaborate pumping schemes, or exotic crystals (e.g., such as BaTiO₂, LiNBO₂) to provide OPC.

Additionally, corner-cube arrays have the added advantage of not suffering from the frequency-scanning problem. However, in order for a corner-cube array to provide OPC in a device such as a semiconductor laser-diode it must first meet several strict criteria; e.g., such as structural coherency, unobstructed external/internal retro-reflection/refraction, all of which is very hard to achieve for sub-millimeter sized structures.

Some current applications require the corner-cube array to be configured to retro-reflect light in a designated pattern or divergence profile. Examples of such corner-cube arrays are described in U.S. Pat. No. 4,938,563 to Nelson, et al. and U.S. Pat. No. 4,775,219 to Appeldorn, et al., which are cited here as representative examples of these types of devices.

Currently, corner-cube arrays are used in flexible retro-reflective tapes, road signs, and various other safety devices and materials. However, in order for corner-cube arrays to be used in reflective tapes, road signs, and safety devices they must exhibit an off-axis retro-reflection of a light source. More specifically, an off-axis retro-reflection corner-cube array, such as those used in stop signs, needs to preferably retro-reflect light toward the eyes (e.g., eyes of the driver of an automobile) instead of retracing the reflected light's original propagation backwards to its light source (e.g., head lights of the automobile being driven).

Retro-reflectors, such as the kind described in ‘Precision crystal corner cube arrays for optical gratings formed by a (100) Silicon planes with selective epitaxial growth’, written by Gerold W. Neudeck, Jan Spitz, Julie C. H. Chang, John P. Denton, and Neal Gallagher, 35 Applied Optics 3466 (Jul. 1, 1996), and U.S. Pat. No. 6,461,003, to Gallagher, et al., would fail to provide OPC if used in the cavity of a laser-diode. This is due to its off-axis retro-reflection of the light source, which explains why the corner-cube arrays produced by Neudeck, et al., exhibit a weak retro-reflection towards the light source. High degrees of retro-reflection is absolutely necessary for OPC to neutralize amplified spontaneous emissions present in a laser's cavity.

An off-axis retro-reflection results for the devices described by Gerold W. Neudeck, et al., when the substrate wafer used to construct the corner-cube arrays exhibits a crystal lattice orientation that is slightly off-axis a few degrees from the original (111) growth direction of the crystal melt the substrate wafer was cut from. More specifically, an off-axis crystal orientation results therein when a substrate wafer is sliced a few degrees off the perpendicular (111) growth direction axis of the crystal melt.

The references listed below describe how these off axis substrate wafers are used not how they are made, regardless, they are cited herein as a source of additional information regarding the prior art of selective overgrowth processing: (1) Neudeck, et al., ‘Precision Crystal Corner-cube arrays for Optical Gratings Formed by (100) Semiconductor Planes with Selective Epitaxial Growth’, 35 Applied Optics 3466 (Jul. 1, 1996); (2) Bashir, et al., ‘Characterization of Sidewall Defects in Selective Epitaxial Growth of Silicon’, 13 Journal of Vacuum Science Technology 923 (1995); (3) Goulding, et al., ‘The Selective Epitaxial Growth of Silicon’, Materials Science and Engineering p. 47 (1993).

More specifically, during the production of certain legacy circuitry, an off-axis crystal orientation, which results when a substrate wafer is sliced a few degrees off the perpendicular (111) growth direction of the crystal melt, is used primarily to promote better (111) crystal growth when using “Liquid Phase Chemical Vapor Deposition” (LPCVD) in (“Metal Organic Chemical Vapor Deposition” (MOCVD), “Metal Organic Vapor Phase Epitaxy” (MOVPE) type reactors, as the substrate wafers are typically angled toward the epi-deposited material's gas-source during.

The invention, as described in its preferred form, solves the off-axis retro-reflection problem by using substrate wafers that are cut on-axis (i.e., wafers a sliced 90° perpendicular to the crystal melt <111> growth direction), and by utilizing “Molecular Beam Epitaxy” (MBE) as the epitaxy growth method. Further, when used together we can create corner-cube arrays that are capable of providing the kᵢₙ=kₒᵤₜ that is indicative of OPC. Another reason why the corner-cube arrays created by Gerold W. Neudeck, et al., cannot be used to provide passive OPC in lasers is because the corner-cubes comprising these corner-cube arrays have pads constructed from SiO₂ and/or Si₃N₄, or some other deposited and lithographically etched material that differs from the substrate material (which were used by Neudeck, et al. to suppress crystal growth along several predefined crystal axis' during corner-cube production), which are located in front of the back-side material entrance of the corner-cube array.

Consequently, if used to provide total internal reflection, these pads (due to the high contrast in refraction exhibited between Silicon-Dioxide or Silicon-Nitride and Silicon) cause anomalous reflections to occur in front of the corner-cube array; thus, neutralizing the OPC capability of the passive PCM (i.e., anomalous reflections cause spatial hole burning to occur for the cavity, which seriously degrades the performance of the laser). For experimental examples demonstrating and describing the anomalous reflection problem, and how it impacts OPC performance, please see ‘Phase Conjugate Laser Optics’, specifically pages 320 to 323, edited by Arnard Brignon and Jean-Pierre Huignard, publish 2004, by John Wiley and Sons, Inc. In the above reference Brignon, et al., used anti-reflection coatings deposited on the laser-diodes as the means to eliminate anomalous reflections occurring between the laser diode's gain-region and the PCM.

Alternatively, if a corner-cube array, as provided by Neudeck, et al., were used to provide external reflection in the cavity of a laser-diode, the laser-diode would fail to laze due to optical losses that occur at the air/metal interface of the light reflecting surface of the corner-cube array.

In addition, corner-cube array comprising retro-reflectors are sometimes arranged to convey information. U.S. Pat. No. 4,491,923 to Look and U.S. Pat. No. 4,085,314 to Schultz, et al., are cited as examples of this type of arrangement. Indeed, wide varieties of systems have been proposed, which incorporate corner-cube reflective elements, such as the optical scanner of U.S. Pat. No. 5,371,608 to Muto, et al., and the satellite defense system of U.S. Pat. No. 4,852,452 to Barry, et al.

Currently, the retro-reflective corner-cube arrays constructed from certain polymers are mass-produced from a tooling patterned after the corner-cube structure of a master mold. For instance, corner-cube retro-reflective sheeting is manufactured by first making a master mold that includes an image of desired corner-cube element geometry. This mold may be replicated using, for example, an electrochemical replication process such as nickel electroplating to produce tooling for forming corner-cube retro-reflective sheeting. U.S. Pat. No. 5,156,863 to Pricone, et al., provides an illustrative overview of a process for forming tooling used in the manufacture of corner-cube retro-reflective sheeting.

Prior art, describes many examples of suitable polymer materials used to construct corner-cube arrays; e.g., Acrylics, all of which generally have a refraction index between 1.5 and 1.6 (e.g., Plexiglas resin from Rohm and Haas), Thermoset Acrylates, Epoxy Acrylates, Polycarbonates, and Polyethylene-based Polyesters, and Cellulose Acetate Butyrates.

Prior art also describes other materials that are used to the construct corner-cube arrays that comprise retro-reflective sheeting; e.g., U.S. Pat. No. 5,439,235 to Smith, et al. Prior art further describes how the retro-reflective sheeting may also include colorants, dyes, UV absorbers, or other additives as needed. Additionally, the prior art describes how it may be desirable in some circumstances to provide corner-cube array comprised retro-reflective sheeting with a backing layer. A backing layer is particularly useful for retro-reflective sheeting that reflects light according to the principles of total internal reflection. A suitable backing layer may be made of any transparent or opaque material, including colored materials that can be effectively engaged with retro-reflective sheeting.

Moreover, prior art further describes suitable backing materials; including: Aluminum Sheeting, Galvanized Steel, and Laminate Polymeric like materials; such as Polymethyl Methacrylates, Polyesters, Polyamids, Polyvinyl Fluorides, Polycarbonates, Polyvinyl Chlorides, Polyurethanes, just to name a few. The backing layer and/or sheet may be sealed in a grid pattern or any other configuration suitable to the retro-reflecting elements. Sealing may be affected by use of a number of methods including ultrasonic welding, adhesives, or by heat sealing at discrete locations on the arrays of reflecting elements, please see, e.g. U.S. Pat. No. 3,924,928, which is incorporated herein for reference purposes only.

However, while these plastic corner-cube arrays might have application in flexible reflective tapes, road signs, and/or used as retro-reflectors in optical systems, such as the one described in U.S. Pat. No. 4,491,923 to Look, et al., and U.S. Pat. No. 4,085,314 to Schultz, et al., the plastic material used to construct the corner-cube arrays will greatly attenuate (due to absorption by said polymers) the laser-field when used in a laser-diode's cavity. Moreover, this is due to laser-diode cavities being highly sensitive to optical loss and consequently, will not laze if the optical loss occurring for said cavity exceeds the optical gain. This is not the case for systems, such as described by U.S. Pat. No. 4,852,452 to Barry, et al., because the corner-cube array used to provide retro-reflection is located external to the laser-cavity of the laser light source used by the system.

Conventional methods for manufacturing the master mold include pin-bundling techniques, direct machining techniques, and laminate techniques. Each of these techniques has various limitations, especially when both small corner-cube dimensions and high optical performance are desired. For the direct machining approach, grooves typically are formed in a unitary substrate to form a corner-cube retro-reflective surface. U.S. Pat. No. 3,712,706 to Stamm, et al. and U.S. Pat. No. 4,588,258 to Hoopman, et al., provide illustrative examples of direct machining techniques.

Direct machining techniques offer the ability to machine very small corner-cube elements (e.g., 1.0 millimeters), which is desirable for producing a flexible retro-reflective sheeting. However, it is not presently possible to produce cube-corner geometries that have very-high coherency and effective apertures at low-entrance angles using direct machining construction techniques. By way of example, the maximum theoretical percent active-aperture of the cube-corner element geometry depicted in U.S. Pat. No. 3,712,706 is approximately 67%. U.S. Pat. No. 5,600,404 to Benson, et al., U.S. Pat. No. 5,585,118 to Smith, et al., and U.S. Pat. No. 5,557,836 to Smith, et al., are cited as additional examples of various cube-corner machining techniques.

In order to achieve the high degree of coherency and higher spatial resolutions necessary for producing passive OPC, the corner-cubes used to comprise the array need to be very small (due to diffraction the optimal corner-cube should have a pitch dimension that equals tens times the wavelength of light the corner-cube array is designed to retro-reflect) and the surfaces of each corner-cube need to be optically flat and should join adjacent surfaces at well-defined angles--even if spacing between adjacent corner-cubes is as large as a few hundred micrometers. Thus, there is a need for smaller, more coherent, corner-cubes.

Consequently, it is preferred to provide for an array of corner-cubes that have a corner-cube spacing of less than 50-μm. Smaller corner-cubes would mean that the OPC reflection would be greater than unity for the PCM. The present invention meets the necessary requirements to create such a structure capable of producing passive OPC, while providing other important benefits and advantages.

### OBJECTS AND ADVANTAGES

Various aspects of the invention are novel, non-obvious, and provide various advantages. While the actual nature of the invention covered herein, may only be determined with reference to the claims appended hereto, certain features, which are characteristic of the preferred embodiment disclosed herein, are described briefly as follows:

a) One feature of the present invention is a corner-cube array that includes a (111) semiconductor substrate and a number of semiconductor crystalline projections generally extending perpendicular from the substrate wafer surface on axis along the (111) crystal lattice direction. The projections each have a corner-cube shape with three generally planar surfaces. The surfaces are generally mutually perpendicular and generally correspond to (100), (010), and (001) crystal axis faces;

b) Another feature of the invention provides for a semiconductor substrate that has a cubic crystalline lattice structure, and a number of non-crystalline (i.e., polycrystalline or sometimes called amorphous semiconductor material), which are generally formed apart from one another in a predetermined pattern along the growth plane of said substrate. These non-crystalline areas are formed when the semiconductor material used to comprise the substrate is made none crystalline as the result of ion and/or proton implantation, which is projected through a mask to produce a predefined pattern of polycrystalline material along the growth plane of the substrate. These amorphous polycrystalline implantation sites made to form within the substrate will be used to spatially control further semiconductor crystal growth on the substrate wafer. Wherein, a number of semiconductor crystalline corner-cube projections will be made to grow out from the growth plane of the substrate wafer. These projections will each have three generally planar surfaces. The projections are spaced apart from each other in accordance with the implanted pattern of amorphous semiconductor material areas, and will be used to provide for a pseudo-phase conjugate mirror comprising a coherent array of corner-cubes;

c) Another feature of the invention provides for a crystalline substrate that has a generally planar first surface substantially corresponding to a first crystal face. A predetermined pattern of amorphous material is defined along the first surface to control crystal growth thereon. A material is epitaxially deposited upon the first surface in order to grow a number of crystals corresponding to the pattern of amorphous material. The crystals will generally have the same chemical composition and crystal lattice arrangement as a good portion of the substrate. The crystals will extend from the first surface to define second, third, and fourth generally planar surfaces. The second, third, and fourth surfaces substantially correspond to second, third, and fourth crystal faces. The second, third, and fourth crystal faces are oblique relative to the first crystal face;

d) Another object of the present invention is to provide for a replication tooling, which may be operated to provide a number of articles each having a corner-cube array shape;

e) Another object of the present invention is to provide for an annealing of the corner-cube array in order to re-crystallize the proton and/or ion implanted areas previously used to control crystal growth so that said areas exhibit same optical properties as the surrounding substrate material; thus, neutralizing anomalous internal reflections that would occur otherwise at the implant locations;

f) Another object of the present invention is to provide for a corner-cube array that is made by processing a substrate having a cubic crystalline lattice. Wherein, a number of crystal growth regions are implanted along the surface during processing. These implant regions are established in a predetermined pattern. A cube-corner shaped projection is epitaxially grown between each of the implant regions. The projections generally extend along an (111) crystal lattice direction with three generally planar surfaces. The surfaces are generally mutually perpendicular to one another and substantially correspond to (100), (010), and (001) crystal faces. This crystal growth technique may be utilized to provide a corner-cube array with cube edges less than 39 micrometers in length;

g) Another object of the present invention is to provide for a totally crystalline corner-cube array comprising of one semiconductor material;

h) Another object of the present invention is to grow corner-cubes having crystal faces that are oblique relative to a crystal face of a substrate on which the cube-corner array is grown;

i) Another object of the present invention is to provide for corner-cubes spaced apart from each other by a distance of <200-μm;

j) Another object of the present invention is to provide for a crystal corner-cube array suitable for making a replication tooling;

k) Another object of the present invention is to provide for a crystal corner-cube array capable of OPC;

1) Another object of the present invention is to provide for a crystalline corner-cube array that can function as a PCM within the cavity of a laser;

m) Another object of the present invention is to provide for a crystal corner-cube array free from anomalous polycrystalline semiconductor pads, which is accomplished via a slow annealing of the corner-cube array to provide for a re-crystallization of the anomalous polycrystalline semiconductor pads; thus, providing for an increase in array coherency; greatly enhancing the OPC capabilities of the corner-cube array.

n) Another object of the present invention is to provide for a polycrystalline corner-cube array, which is accomplished via a fast annealing of the corner-cube array to provide for to poly-crystallization of the entire corner-cube array; thus, providing for an increase in array coherency; greatly enhancing the OPC capabilities of the corner-cube array.

Further objects, features, aspects, advantages, and benefits of the present invention will become apparent from the drawings and description contained herein.

### SUMMARY OF THE INVENTION

In accordance with the present invention a method to construct either a poly-crystalline or a crystalline corner-cube array comprised PCM, using a method, where proton and/or ion implantation is used to form a predetermined pattern of amorphous poly-crystalline implant sites, which are used to suppress and control crystal growth for the (100), (010), and (001) crystal lattice directions. This results in the growth of coherent corner-cubes; forming an array in the (111) crystal lattice direction of the substrate. Further, the present invention also utilizes either a slow or fast annealing of the corner-cube array comprised substrate wafer to remove material discontinuities (via re-crystallization or poly-crystallization of the material comprising the corner-cube array, respectively) that would normally otherwise degrade the OPC capability of the corner-cube array.

### BRIEF DESCRIPTION OF THE DRAWINGS

FIG. 1 is plan-view drawing of a corner-cube array.

FIG. 2 is a schematic cross-section of the corner-cube array.

FIG. 3 is a flow diagram of a processing system of the present invention.

FIG. 4 is a schematic of a wafer processed by the system of FIG. 3.

FIG. 5 is a plan view of the wafer of FIG. 4 at a selected processing stage.

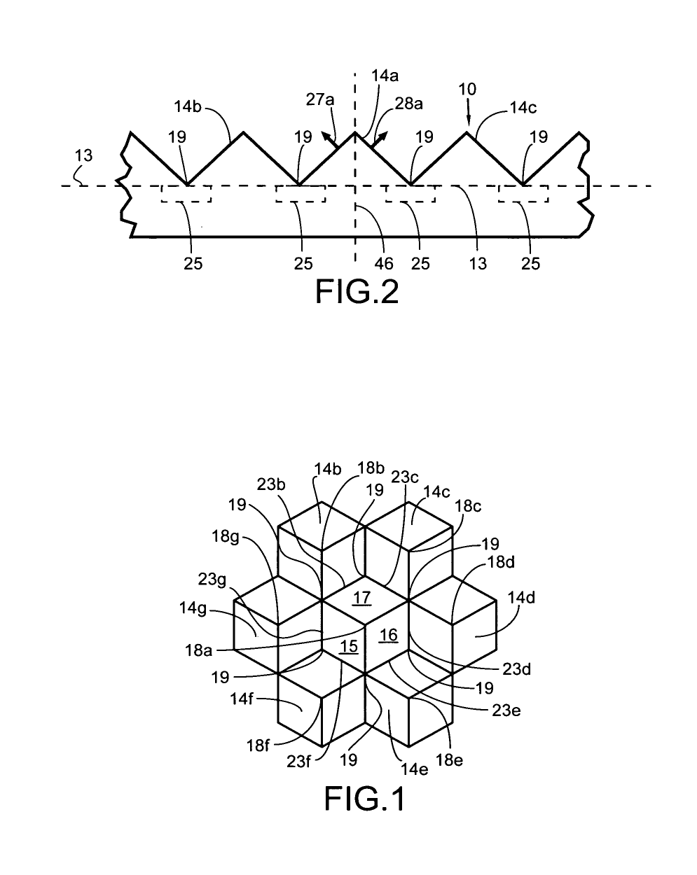

### DETAILED DESCRIPTION—FIGS. 1, 2, 3, 4, AND 5—PREFERRED EMBODIMENT

For the purposes of promoting an understanding of the principles of the invention, reference will now be made to the embodiment illustrated in the drawings and specific language will be used to describe the same. It will nevertheless be understood that no limitation of the scope of the invention is thereby intended. Any alterations and further modifications in the described device, and any further applications of the principles of the invention as described herein are contemplated as would normally occur to one skilled in the art to which the invention relates. FIG. 1 depicts a crystalline corner-cube array device 10 of the present invention. Device 10 has a substrate 11 supporting a corner-cube array 10.

Further, FIG. 1 provides a cutaway view of substrate 11 corresponding to the removal of a part of corner-cube array 10. Substrate 11 is formed from a semiconductor material (e.g., GaAs, InP), having a common cubic crystalline lattice structure, and also being a semiconductor that does not form native oxides as the direct result of proton and/or ion implantation, as would be the case with Silicon substrates.

Prior to formation of the corner-cube array 10, substrate 11 has surface 13 that is substantially coplanar with a (111) crystal face of substrate 11. Accordingly, the (111) crystal lattice direction is generally perpendicular to the view plane of FIG. 1. Corner-cube array 10 is formed from a semiconductor on substrate 11. Corner-cube array 10 has a number of projections having a corner-cube shape. These projections extend from substrate 11 along the (111) crystal lattice direction. A few of these projections are specifically designated by reference numerals 14a-14g and are collectively referred to as projections 14. For projection 14a, planar surfaces 15, 16, and 17 are designated. Surfaces 15, 16, 17 are generally planar and mutually perpendicular to one another.

Moreover, surfaces 15, 16, 17 intersect each other to define a trihedral shape with apex 14a. Notably, surfaces 15, 16, 17 are each oblique with respect to the (111) crystal face of substrate 11. Projections 14a-14g correspondingly have apexes 18a-18g. Apexes 18a-18g are collectively referred to as apexes 18. Similar to projection 14a, the remaining projections 14 have a trihedral shape generally defined by three mutually perpendicular surfaces. Furthermore, it should be recognized that for the preferred embodiment, the pattern of projections 14, as illustrated in FIG. 1, is repeated numerous times to provide the crystalline corner-cube array device 10. As a representative example of each projection 14, projection 14a is further described. Projection 14a has adjoining edges 23b-23g where a surface of a corresponding one of surrounding projections 14b-14g is met.

Moreover, the surfaces 15, 16, 17 of projection 14a each meet the surrounding surfaces at approximately right angles. Notably, the uniform pattern of corner-cube array 10 provides that each projection 14 is generally sized and shaped the same as the others and each projection 14 within the pattern is surrounded by six neighboring projections 14 in a generally symmetric arrangement. Further, it should be noted by reference to projection 14a, that each projection 14 meets two surrounding projections in an alternating pattern of corner-cube shaped recesses 19 and intersection points 20. Thus, at each recess 19 and point 20, three projections 14 meet.

Referring additionally to FIG. 2, a schematic cross-section of substrate 11 and corner-cube array 10, is illustrated. FIG. 2 depicts (111) crystal plane 21 which substantially coincides with surface 22. Plane 21 generally provides an interface with substrate 11 for each projection 14. Axis 24 represents the (111) crystal lattice direction and is shown intersecting projection 14a. Similarly, other projections 14 of corner-cube array 10 project from plane 21 along axis 24. At each recess 19, an implant site 25 is buried in plane 21. Implant sites 25 are preferably formed when Hydrogen protons, Gallium ions, or Arsenic ions are injected (i.e., implanted) through a mask into the substrate surface 21 forming a multitude of rectilinear areas of polycrystalline material, which are spaced apart from one another in a predetermined pattern along plane 21.

Its important to note that Gallium (i.e., ions of Gallium) or Arsenic (i.e., ions of Arsenic) are the preferred implant materials for substrate material GaAs, while Indium (i.e., ions of Indium) or Phosphorous (i.e., ions of Phosphorous) is the preferred implant material for substrate material InP. As prior art shows, implant material is typically implanted to create circuits (i.e., material channels providing conductive or resistive electrical properties that contrast the surrounding semiconductor material) within a substrate material, however, to accomplish this desired result the implant material must typically comprise of electrically conducting or resisting atoms (e.g., Zn, Be, Mg, H, He, and O ions are regularly used as implant material in GaAs substrates). For an early prior art example of ion implantation, please see U.S. Pat. No. 3,936,321 to Daizaburo Shinoda, et al.

The reason for using an implant material that corresponds to the substrate 11 material is so that the substrate 11 can later on (after implantation) be annealed so as to re-crystallize the implant regions 25; thus, providing a corner-cube array that is entirely crystalline (i.e., contrastingly, not having oxide and/or nitride pads being present within the corner-cube array 10 causing anomalous internal reflections). Other implant materials for other substrate materials can be utilized and should be obvious to one skilled in the art.

Projections 14 are each formed as a cubic shaped semiconductor crystals on surface 13 (plane 21) of substrate 11 through epitaxial growth techniques. These crystals grow into each other, creating adjoining edges (such as edges 23b-23g) that form a corner-cube array 10. Preferably, the crystals overgrow the implanted areas 25 as typified by the overgrowth region designated by reference numeral 19 in FIG. 2. This epitaxial growth is preferably controlled to maximize coverage over each implant site 25 by the corresponding projections 14, so that the intersection of three mutually perpendicular surfaces results, defining recesses 19. For this crystalline structure, surfaces 15, 16, 17 of projection 14a generally correspond to (100), (010), and (001) cubic crystal lattice faces, which are the common crystal growing planes for (111) material epitaxy. Crystal lattice directions (010) and (001) are shown in FIG. 2 as arrows 27a, 28a, respectively. The other projections 14 have comparable coherent crystallographic features.

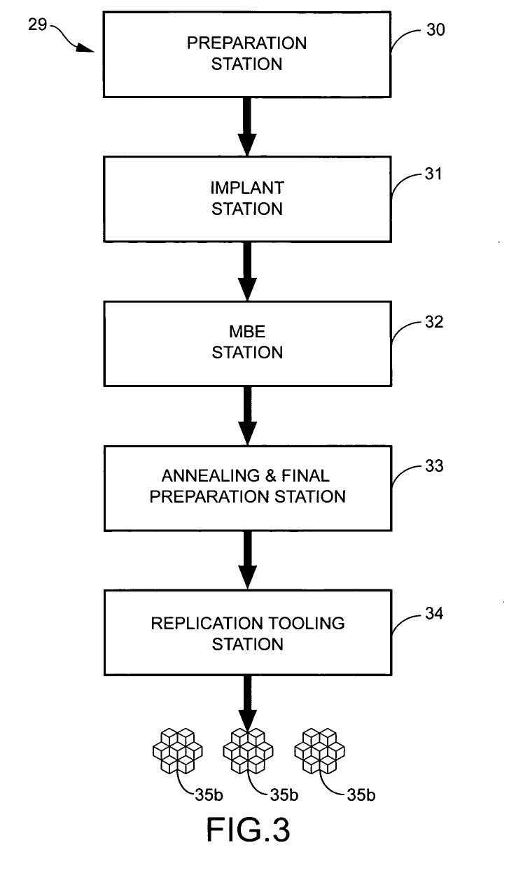

A processing system 29 is depicted by FIG. 3. System 29 provides for a crystal corner-cube array device 10 as described in connection with FIGS. 1 and 2 with like reference numerals referring to like features. Collectively referring to FIGS. 1-5, at preparation station 30, a (111) semiconductor wafer 11a is selected and prepared for subsequent processing. Wafer 11a includes substrate 11 as depicted in FIGS. 1 and 2. At preparation station 30 Protons (e.g., positive charged Hydrogen atoms) and/or ions (e.g., negative charged Gallium or Arsenic atoms) are implanted through a mask into the substrate material 11 (e.g., substrate of Gallium-Arsenide).

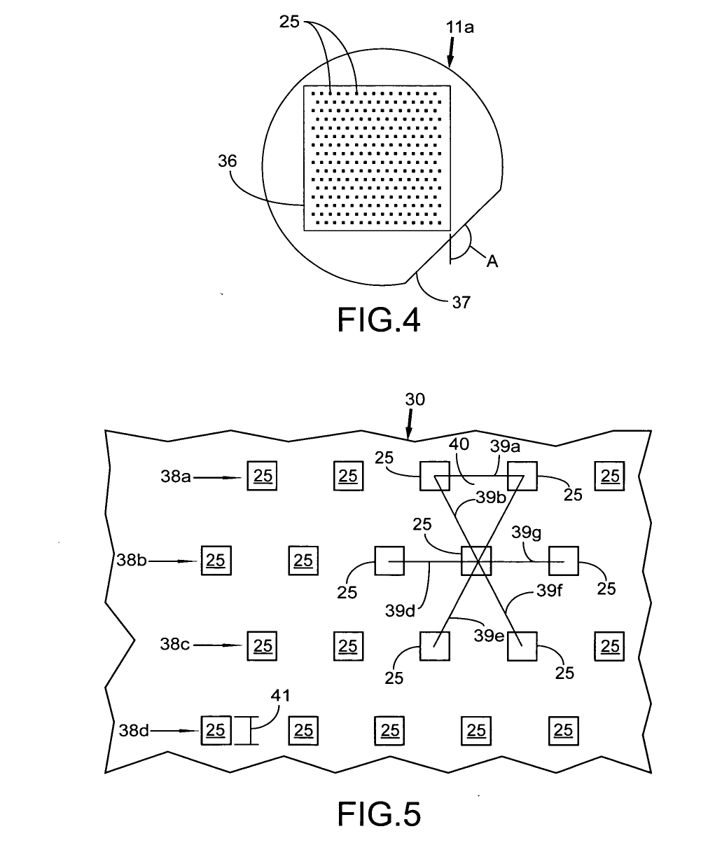

Moreover, pattern 36 includes a number of element sites 25 schematically represented by dots in FIG. 4. Preferably, implant sites 25a are defined with generally straight edges, which may be aligned with, wafer flat 37. Preferably, flat 32 is formed to be approximately perpendicular to the (110) crystal lattice direction of wafer 11a. It has been found that the orientation and geometry of implant sites 25a relative to flat 37 alters the corner-cube arrangement of projection 14. Angle A between pattern 36 and flat 37 is illustrated in FIG. 4, which may be altered to provide different cubic crystal structures.

Preferably, the implant sites 25a are generally square shaped having its perimeter generally parallel with flat 37. In FIG. 5, an enlarged view of a portion of the implant sites 25a are illustrated along a part of substrate 11. Notably, implant sites 25a are arranged in staggered rows 38a-38d with surface 13 being exposed there between. Linear segment 39a represents center-to-center spacing between implant sites 25a adjacent to one another in a common row 38a. Linear Segments 39b-39g represent center-to-center spacing between a selected implant site 25a and each of six of the closest surrounding implant sites 25a.

Preferably, the spacing that lies between adjacent implant sites of a row is generally the same as represented by segment 39a. More preferably, the spacing between all of the six closest surrounding implant sites 25a are the same such that lineal segments 39a-39g each represent approximately equal distances. In a most preferred embodiment, each implant site 25a is equidistant from its nearest neighboring implant sites 25a.

In a preferred micro-structural embodiment of the crystal corner-cube array, the distance represented by segments 39a-39g is less than about 200-μm. In a more preferred micro-structural embodiment, the distance represented by segments 39a-39g is less than about 50 micrometers. In a most preferred micro-structural embodiment, the distance represented by segments 39a-39g is no more than about 10 micrometers. Segments 39a, 39b, 39c generally define an equilateral triangle region 40. Region 40 corresponds to a base of one of projections 14 having implant sites 25a at each triangle corner.

Notably, an apex 18 of a projection 14 corresponding to region 40 is generally equidistant from each of implant sites 25a in the respective corners of the triangular region. The staggered arrangement of implant rows 38a-38d generally provides a uniform pattern of adjacent equilateral triangular growth regions each similar to region 40. These triangular shaped areas correspond to adjacent crystal growth sites suitable for the uniform distribution of trihedral crystal projections 14.

Preferably, the staggered row pattern of FIG. 5 is repeated numerous times to provide a crystal corner-cube array. FIG. 5 also depicts distance segment 41 corresponding to an edge of one of implant sites 25a. Preferably, for a micro-structural corner-cube array embodiment, implant sites 25 are about 1- to 5-μm² in size. In FIG. 3, “Molecular Beam Epitaxy” MBE reactor 32 is utilized for the deposition of semiconductor in a controlled amount to form projections 14. During MBE deposition, the crystal growth rate within the triangular regions corresponding to region 40 is differentiated as a function of distance from implant sites 25a to provide a trihedral crystal shape.

Additionally, a controlled degree of growth onto the polycrystalline implant sites 25 is permitted to sharply define recesses 19. In essence, the amorphous/polycrystalline implant sites 25a resist nucleation of semiconductor crystals relative to the exposed triangular crystal growth regions (such as region 40) of plane 13 situated therein, between. The growth planes of the semiconductor are in the (100) direction. As a result, corner-shaped projections are each formed during MBE deposition 32, as various crystal nucleation sites within a corresponding triangular region grow into one another.

Moreover, this process may be used with other crystal growth suppression amorphous/polycrystalline implant materials and implant site patterns, including varied depths of suppression sites and spacing between suppression sites, respectively, to adjust the size of the crystal projections 14. Besides being formed using Gallium and/or Arsenic, implant sites 25a may be formed from other semiconductor crystal growth suppression materials; e.g., such as Indium and/or Phosphorous for InP substrate material. Additionally, other types of crystal-growth suppression techniques or elements may be employed as would occur to one skilled in the art.

After projections 14 have been formed in the MBE reactor 32, the resulting corner-cube array is processed at final processing station 33. At this point, the PCM 10 will undergo fast or slow annealing, and may be coated or passivated as required for a particular application as well (i.e., application being typically determined by wavelength of light needing retro-reflection).

In addition, FIG. 3 depicts one other process embodiment, where device 10 is employed as a master mold or template to replicate low-cost corner-cube arrays using replication-tooling 34. Replication tooling 34 includes replication mold 35a that is patterned from device 10. Tooling 34 is employed to form articles 35b having a corner-cube array shape substantially corresponding to corner-cube array 10. Generally, the shape of each article 35b is imparted by contact with replication mold 35a. A schematic representation of mold 35a is shown as part of tooling 34, and articles 35b are schematically illustrated in FIG. 3 as production output of tooling 34.

Moreover, a mold 35a may be constructed from device 10 using a precision replication technique, such as; e.g., nickel electroplating to form a negative copy of corner-cube array 10. Electroplating techniques are well known to one of ordinary skill in the retro-reflective arts. For more information please see; e.g., U.S. Pat. Nos. 4,478,769 and 5,156,863 to Pricone, et al. The negative copy of corner-cube array 10 embodied in mold 35a may then be used for forming retro-reflective articles 35b having a positive copy of the corner-cube array 10.

More commonly, additional generations of electroformed replicas are formed and assembled together into a larger mold. It will be noted that the original working surfaces of the corner-cube array, or positive copies thereof, could also be used as an embossing tool to form retroreflective articles 35b. A master mold may be made in accordance with the present invention to provide tooling with a structured surface suitable for the mass production of retro-reflective PCMs.

Moreover, the tooling may be made using electroforming techniques or other conventional replicating technology. The surface of the tooling may define identical corner-cube elements or may include corner-cube elements of varying sizes, geometries, or orientations provided by one or more master molds. Typically, the surface of this tooling sometimes referred to in the art as a ‘stamper’, which will contain a negative image of the corner-cube elements of the master mold. A single master mold replica may be used as a stamper for forming a retro-reflecting PCM. One of ordinary skill in the retro-reflective PCM arts will recognize that the working surface of each corner-cube array functions independently as a retro-reflector so that adjacent arrays in a mold formed from several replicas of one or more master molds may not need to be positioned at precise angles or distances relative to one another in order to perform as desired.

Alternatively, retro-reflecting PCMs may be manufactured as a layered product by casting the corner-cube elements against a preformed film as taught in U.S. Pat. No. 3,180,340 or by laminating a preformed film to preform cube-corner elements. By way of example, an effective PCM may be manufactured using a nickel mold formed by electrolytic deposition of nickel onto a master mold. The electroformed mold may be used as a stamper to emboss the pattern of the mold onto a glass film approximately 390-μm thick having an index of refraction of about 1.59. The mold may be used in a press with the pressing performed at a temperature of approximately 515-1540° C., depending upon the type of glass or other optically suitable material.

Moreover, it should be further appreciated that the present invention provides a technique to grow crystalline structures shaped like cube-corners onto a crystal face of a substrate, where crystalline structures have crystal growth planes, which are oblique to the crystal face of the substrate. The crystal structures may be grown in patterns utilizing selective epitaxial growth processes.

Typically, crystal growth selectivity is provided by establishing an array of non-crystalline material that resist nucleation of the crystals being grown. Using MBE, uniform epitaxial growth is done within a “Ultra-High Vacuum” (UHV) environment to produce coherent corner-shaped recesses. As used herein, a “(111) substrate,” “(111) semiconductor substrate,” “(111) wafer,” and “(111) semiconductor wafer” each refer to a device having a surface that substantially corresponds to a (111) crystal face.

### DETAILED DESCRIPTION—EXPERIMENTAL SECTION

The following experimental examples are provided to exemplify selected aspects of the present invention, and are to be considered only as being illustrative, and not restrictive in character. In a preferred experimental set-up, a four inch (111) undoped GaAs substrate wafer is utilized. The wafer was first processed using a standard implantation technique to define 155 dies, by implanting Gallium ion into selected regions of the GaAs substrate wafer, and arranged generally planar with the GaAs wafer, while substantially corresponding to the (111) semiconductor crystal face. Each die is defined as 16 different spatial patterns of generally square Gallium and/or Arsenic ion implant sites, which were arranged into a predetermined pattern along the undoped (111) GaAs substrate wafer.

Moreover, the implant sites were arranged in staggered rows for each different pattern. The patterns were established by varying the center-to-center spacing of the implant sites from about 3- to 39-μm, and the implant site edge-size from about 1- to 5-μm. After formation of the implant sites, crystal growth was performed by placing the (111) GaAs semiconductor wafer into MBE reactor. In the MBE reactor, the (111) GaAs semiconductor wafer was positioned onto a rotating wafer holder/heater jig where it was rotated and exposed to a Gallium flux as the result of solid Gallium being vaporized by an electron beam. The vaporized Gallium it is made to epitaxially deposit onto the rotating preheated GaAs substrate wafer. A high vacuum of 10⁻⁹ mbar was maintained for the MBE reactor and a temperature of about 500° C. was maintained for the GaAs wafer during material epitaxy.

Alternatively, “Gas-Source Molecular Beam Epitaxy” (GSMBE) may preferably be used to grow the crystal corner-cubes. Moreover, MBE or GSMBE processes were utilized to grow approximately 1.5-μm of epitaxial GaAs semiconductor crystal, as measured by the “Reflection High Energy Electron Diffraction” (RHEED) connected to the reactor. As monitored, the growth rate of epitaxial crystal on the (111) GaAs semiconductor substrate wafer was about 0.1 micrometers per-minute. Further, edge of each implant site was generally parallel to the flat of the (111) GaAs semiconductor substrate wafer. Surface roughness was determined to be less than 20 Angstroms for the crystal facets of each corner-cube structure comprising an array.

Once the GaAs substrate cooled down to room temperature it was reheated in the final preparation annealing station 33 (which could comprise laser annealing) to approximately 300° to 500° C., where it was next made to undergo a slow cooling (i.e., slow annealing) process. The ramp down of temperature (e.g., 300° to 500° C.) occurred over a period of approximately eight hours. This slow ramp-down cooling period would allow the implant sites 25 to nucleate properly (i.e., re-crystallize). The result was a re-crystallization of the implant sites 25, which provided an greater optical uniformity for the entire corner-cube array, and the subsequent elimination of any anomalous reflections that would otherwise seriously degrade the OPC performance of the PCM.

### DETAILED DESCRIPTION—ALTERNATIVE EMBODIMENT

In an alternative embodiment, comparable conditions were utilized, except triangular-shaped proton and/or ion implant sites were employed. It was discovered that triangular implant sites are more resistant to lateral overgrowth compared to the square implant sites utilized in the preferred embodiment. Further, it was found through analysis that spacing between implant sites may be varied to adjust cubic projection height from the epitaxial crystal growth process, and that growth may be controlled by adjusting the amount of gas and/or vaporized construction materials utilized in the MBE reactor.

In an alternative embodiment, a fast annealing of the corner-cube array is used in place of the more preferred slow process of annealing. Once the GaAs substrate cools down to room temperature it is reheated in the final preparation annealing station 33 to approximately 500° to 1000° C., where it will next undergo a fast cooling (i.e., fast annealing) process. The ramp down of temperature (e.g., 500° to 1000° C.) will occur over a period of approximately 30 minutes to 1 hour. Contrastingly, this will force the crystal material surrounding the non-crystal proton and/or ion implant sites 25 to undergo a disassociation of crystalline structure (i.e., poly-crystallization of the material surrounding the poly-crystalline implant sites). The result is a poly-crystallization of the material surrounding the non-crystal implant sites 25, which results in a greatly enhanced optical uniformity for the entire corner-cube array and therefore, the elimination of any anomalous reflections that seriously degrade OPC performance of the PCM.

### FINAL CONCLUSIONS AND STATEMENTS

All publications, patents, and patent applications cited in this specification are herein, incorporated by reference as if each individual publication, patent, or patent application were specifically and individually indicated to be incorporated by reference and set forth herein. While the invention has been illustrated and described in detail in the drawings and foregoing description, the same is to be considered as illustrative and not restrictive in character, it being understood that only the preferred embodiment has been shown and described and that all changes and modifications that come within the spirit of the invention are desired to be protected.

What I claim my invention is:

1. A combination, comprising: a gallium-arsenide substrate having a generally cubic crystal lattice; a number of implant sites positioned apart from one another in a predetermined spatial pattern, said sites being generally spaced along a plane substantially coplanar with a crystal lattice face of said substrate, said sites being constructed when a selected implant material is injected into said substrate and used to selectively control subsequent growth of gallium-arsenide crystal projections, which are made to extend from said substrate, said projections each having three generally planar surfaces each obliquely oriented with respect to said substrate, said projections being spaced apart from the other in accordance with said predetermined pattern of said implant sites.

2. The combination of claim 1 wherein said projections each generally have a trihedral shape to define a corner cube array suitable for optical phase conjugation.

3. The combination of claim 2 wherein said pattern provides a generally uniform distribution of said projections along at least a portion of said substrate.

4. The combination of claim 1 wherein said implants are arranged in a number of staggered rows.

5. The combination of claim 1 wherein center-to-center spacing between adjacent groups of said implant sites is no more than about 200 micrometers.

6. The combination of claim 1 wherein said substrate generally corresponds to a (111) crystal plane, where said projections generally extend along the (111) crystal lattice direction, and said surfaces of said projections generally correspond to (100), (010), and (001) crystal faces.

7. The combination of claim 1 wherein said pattern defines a group of said implant sites that are each generally equidistant from six adjacent members of said sites.

8. The combination of claim 6 wherein said implant sites comprised one of gallium or arsenic injected ions.

9. A method, comprising: selecting a crystalline substrate having a generally planar first surface substantially corresponding to a first crystal face; defining a predetermined implant pattern along the first surface to control crystal growth thereon; and depositing a material on the first surface to grow a number of crystals corresponding to the implant pattern, the crystals having generally the same chemical composition and crystal lattice arrangement as at least a portion of the substrate, the crystals extending from said first surface to define second, third, and fourth generally planar surfaces, the second, third, and fourth surfaces substantially corresponding to second, third, and fourth crystal faces, the second, third, and fourth crystal faces being oblique relative to said first crystal face.

10. The method of claims 9, wherein said substrate has a cubic crystal lattice structure, the first crystal face substantially corresponds to a (111) crystal plane, the second crystal face substantially corresponds to a (100) crystal plane, the third crystal face substantially corresponds to a (010) plane, and the fourth crystal face substantially corresponds to a (001) crystal plane.

11. The method of claim 10, wherein the substrate is generally a single gallium-arsenide crystal and the compound is gallium-arsenide.

12. The method of claim 10, wherein the substrate is generally a single indium-phosphide crystal and the compound is indium-phosphide.

13. The method of claim 9, wherein said defining includes establishing a number of implant sites on the first surface to provide the pattern.

14. The method of claim 12, wherein said defining includes providing said implant sites into staggered rows.

15. The method of claim 12, wherein said implants are constructed using at least one hydrogen protons, or gallium or arsenic ions.

16. The method of claim 9, wherein said depositing includes epitaxially growing the crystals by at least one of gas-source molecular beam epitaxy or molecular beam epitaxy, and the crystals are each formed with the second, third, and fourth surface being generally mutually perpendicular to define a trihedral shape with an apex.

17. The method of claim 9, wherein the crystals generally define a corner cube array and further comprising forming a replication mold with the corner cube array.

18. A corner cube array, comprising: a gallium-arsenide substrate; a number of gallium-arsenide crystal projections deposited on said substrate to generally extend away from the substrate along a (111) crystal lattice direction, said projections each having a cube-corner shape with three generally planar surfaces, said surfaces being generally mutually perpendicular and substantially corresponding to (100), (010), and (001) crystal faces; and a number of implant sites arranged along said substrate to define a crystal growth pattern,
wherein said projections each have generally the same size and shape and have a generally uniform distribution along at least a portion of said substrate.

19. The corner cube array of claim 18, wherein said implants include a number of non-crystalline areas generally spaced apart from one another along growth plane of said substrate, said plane substantially corresponds to the (111) crystal face, and said implants are each made from at least one positive charged hydrogen, or at least one negative changed gallium or negative charged arsenic.

20. The corner cube array of claim 18, wherein said surfaces intersect one another to form an apex, and said apex is generally equidistant from three closest surrounding members of said implants.

21. The corner cube array of claim 18, wherein said substrate is a gallium-arsenide wafer having a flat substantially corresponding to the [110] crystal lattice direction, and said implants each have an approximately straight edge oriented generally parallel with said flat.

22. A corner cube array, comprising: a gallium-arsenide substrate; a number of gallium-arsenide crystal projections deposited on said substrate to generally extend away from the substrate along a (111) crystal lattice direction, said projections each having a corner-cube shape with three generally planar surfaces, said surfaces being generally mutually perpendicular and substantially corresponding to (100), (010), and (001) crystal faces,
wherein said projections each have generally the same size and shape and have a generally uniform distribution along at least a portion of said substrate and
wherein, said projections each have an apex, said apex of one of said projections being spaced apart from said apex of another of said projections by no more than 1 micron.

23. A method for making a phase conjugate mirror, comprising: processing a gallium-arsenide substrate having a cubic crystal lattice, the substrate having a surface substantially corresponding to a (111) crystal face; establishing a number of gallium-arsenide crystal growth regions along the surface during said processing, said regions being established in a predetermined pattern, and epitaxially growing a corner-cube shaped projection on each of the regions, the projection generally extending along a (111) crystal lattice direction with three generally planar surfaces, the surfaces being generally mutually perpendicular to one another and substantially corresponding to (100), (010), and (001) crystal faces.

24. The method of claim 23, wherein said establishing includes an ion implant processing of the substrate to provide for a number of growth suppression sites being parallel with growth plane of substrate surface.

25. The method of claim 23, wherein said establishing includes an proton implant processing of the substrate to provide for a number of growth suppression sites being parallel with growth plane of substrate surface.

26. The method of claim 23, wherein said epitaxially growing includes exposing the substrate to slow annealing to provide for recrystallization of the implant sites.

27. The method of claim 23, wherein said epitaxially growing includes exposing the substrate to fast annealing to provide for poly-crystallization of material surrounding implant sites.

28. The method of claim 23, wherein the regions are defined by a number of spaced apart gallium-arsenide implant sites, and further comprising inhibiting gallium-arsenide crystal growth on said sites during said exposing by adjusting gallium-arsenide gas-source amount.

29. The method of claim 23, further comprising maintaining a vacuum of 10⁻⁹ mbar, and a temperature of about 970 degrees celsius in the molecular beam epitaxy reactor during said exposing.

30. The method of claim 23, further comprising forming replication tooling from the corner-cube array.

31. The method of claim 30, further comprising a number of articles with the tooling, the articles each having a surface structure corresponding to the corner-cube array.

32. The method of claim 30, wherein said forming includes electroplating the corner-cube array to form a replication mold.

33. A method providing: a corner-cube array having a gallium-arsenide substrate with a generally cubic crystal lattice and a number of gallium-arsenide crystal projections extending from said substrate, the projections each having three generally planar surfaces, the surfaces each being generally obliquely oriented with respect to a plane of said substrate, the plane substantially corresponding to a (111) crystal face, the projections being oriented along the plane to provide a predetermined corner-cube array pattern, the device including a number of implant sites spaced apart from one another along the substrate to define a pattern; and forming a number of corner-cube array articles having a shape substantially corresponding to the corner-cube array pattern, wherein the articles each have a number of cube-corner projections spaced apart from each other by no more than 1 micron.
